(19) United States
(12) Patent Application Publication
(10) Pub. No.: US 2009/0261332 A1
(43) Pub. Date: Oct. 22, 2009

(54) THIN FILM TRANSISTOR ARRAY PANEL, FABRICATING METHOD THEREOF AND FLAT PANEL DISPLAY HAVING THE SAME

(75) Inventors: Jung-Han SHIN, Yongin-si (KR); Seon-Pil JANG, Seoul (KR); Min-Ho YOON, Seoul (KR)

Correspondence Address: H.C. PARK & ASSOCIATES, PLC, 8500 LEESBURG PIKE, SUITE 7500, VIENNA, VA, 22182, US

(73) Assignee: Samsung Electronics Co., Ltd., Suwon-si (KR)

(21) Appl. No.: 12/352,099

(22) Filed: Jan. 12, 2009

(30) Foreign Application Priority Data
Apr. 17, 2008 (KR) 10-2008-0035705

(51) Int. Cl. H01L 27/00; H01L 21/02

(52) U.S. Cl. 257/59; 438/29; 257/E27.06; 257/E21.002

(57) ABSTRACT

A thin film transistor array panel includes a substrate, a gate line disposed on the substrate and having a gate electrode, a gate insulating layer disposed on the gate line, a data line disposed on the gate insulating layer and crossing the gate line, a source electrode connected to the data line, a drain electrode spaced apart from the source electrode, a semiconductor layer connected to the source and drain electrodes to form a channel, a light blocking layer disposed on the semiconductor layer to block light incident to the semiconductor layer, and a pixel electrode contacting the drain electrode.

### CROSS-REFERENCE TO RELATED APPLICATION

This application claims priority from and the benefit of Korean Patent Application No. 10-2008-0035705, filed on Apr. 17, 2008, which is hereby incorporated by reference for all purposes as if fully set forth herein.

### BACKGROUND OF INVENTION

1. Field of the Invention

The present invention relates to a thin film transistor (TFT) array panel, a fabricating method thereof, and a flat panel display having the TFT array panel.

2. Discussion of the Background

With the development of information technologies, the demand for high-performance display apparatuses capable of displaying various types of information, such as videos, graphics, and characters, has greatly increased. In particular, technology related to a flat panel display, such as a liquid crystal display (LCD) or an electrophoresis display apparatus, which is thin and operates at a low voltage, has rapidly grown.

Such flat panel displays may have various structures according to the type thereof. In general, the flat panel displays include a TFT array panel on which TFTs serving as switching devices are formed.

A TFT includes a semiconductor layer to form a channel serving as a current path between a source electrode and a drain electrode. Recently, an organic TFT, in which a semiconductor layer is formed by dropping ink containing organic semiconductor material through an inkjet method, has been actively developed.

However, if an organic TFT is exposed to external light, device characteristics of the organic TFT may be degraded, thereby causing the display quality to deteriorate.

### SUMMARY OF INVENTION

The present invention provides a TFT array panel that may prevent device characteristics from deteriorating due to external light.

The present invention also provides a method of fabricating the TFT array panel.

The present invention also provides a flat panel display including the TFT array panel.

Additional features of the invention will be set forth in the description which follows, and in part will be apparent from the description, or may be learned by practice of the invention.

The present invention discloses a TFT array panel including a substrate, a gate line, a gate insulating layer, a data line, a source electrode, a drain electrode, a source electrode, a semiconductor layer, a light blocking layer, and a pixel electrode. The gate line is disposed on the substrate and has a gate electrode. The gate insulating layer is disposed on the gate line. The data line is disposed on the gate insulating layer and crosses the gate line. The source electrode is connected to the data line and the drain electrode is spaced apart from the source electrode. The semiconductor layer is connected to the source and drain electrodes to form a channel. The light blocking layer is disposed on the semiconductor layer to block light incident to the semiconductor layer. The pixel electrode contacts the drain electrode.

The present invention also discloses a method of fabricating a TFT array panel including forming a gate electrode and a gate line on a substrate. A gate insulating layer is formed on the gate line. A source electrode, a drain electrode, and a data line are formed on the gate insulating layer. A semiconductor layer is formed between the source and drain electrodes. A light blocking layer is formed to block light while overlapping with the semiconductor layer. A pixel electrode is formed to contact the drain electrode.

The present invention also discloses a flat panel display including a TFT array panel, a common electrode array panel, and electrophoresis particles. The common electrode array panel faces the TFT array panel. The electrophoresis particles are disposed between the TFT array panel and the common electrode array panel. The TFT array panel includes a substrate, a gate line, a gate insulating layer, a data line, a source electrode, a drain electrode, a source electrode, a semiconductor layer, a light blocking layer, and a pixel electrode. The gate line is disposed on the substrate and has a gate electrode. The gate insulating layer is disposed on the gate line. The data line is disposed on the gate insulating layer and crosses the gate line. The source electrode is connected to the data line and the drain electrode is spaced apart from the source electrode. The semiconductor layer is connected to the source and drain electrodes to form a channel. The light blocking layer is disposed on the semiconductor layer to block light incident to the semiconductor layer. The pixel electrode contacts the drain electrode.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a layout view of a TFT array panel according to an exemplary embodiment of the present invention.

FIG. 2 is a sectional view taken along line I-I′ of the TFT array panel shown in FIG. 1.

FIG. 3 is a sectional view of a TFT array panel according to another exemplary embodiment of the present invention.

FIG. 4A, FIG. 4B, FIG. 4C, FIG. 4D, FIG. 4E, FIG. 4F, FIG. 4G, and FIG. 4H are sectional views showing a method for manufacturing a TFT array panel according to an exemplary embodiment of the present invention.

FIG. 5 is a graph showing a result obtained by performing an exposure experiment relative to an organic TFT unit device without a light blocking layer, and shows V_{GS}-I_{D} curves before and after the unit device is subject to an exposure process.

FIG. 6 is a graph showing a result obtained by performing an exposure experiment relative to an organic TFT unit device using the light blocking layer and an organic TFT unit device without a light blocking layer, and shows V_{GS}-I_{D} curves before and after the unit devices are subject to an exposure process.

FIG. 7 is a sectional view of a flat panel display having a TFT array panel according to an exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

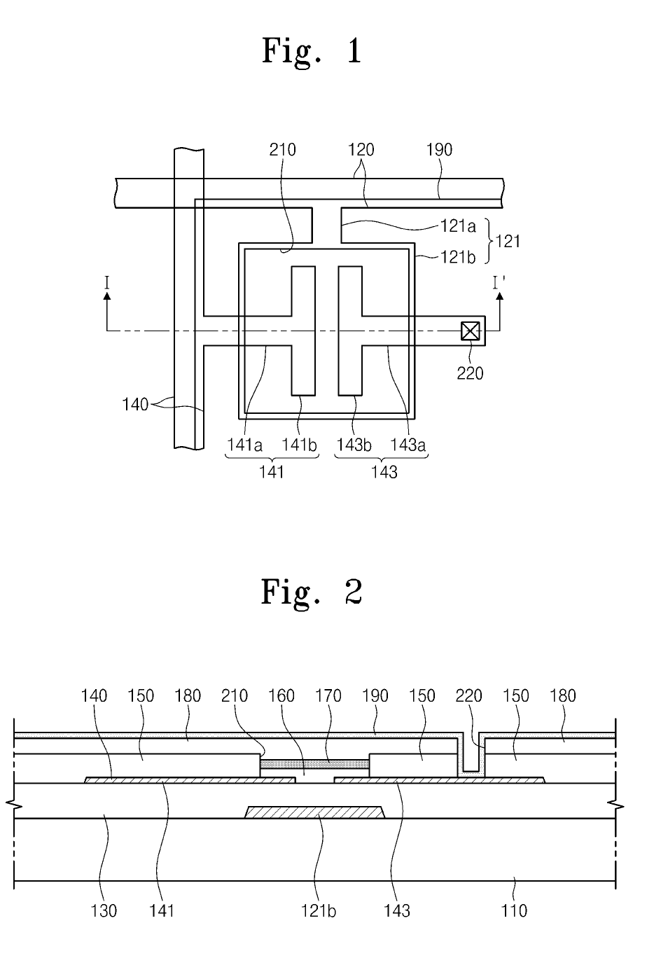

Hereinafter, a TFT array panel according to one exemplary embodiment of the present invention will be described with reference to FIG. 1 and FIG. 2.

FIG. 1 is a layout view of the TFT array panel according to an exemplary embodiment of the present invention and FIG. 2 is a sectional view taken along line I-I′ of the TFT array panel shown in FIG. 1.

Referring to FIG. 1 and FIG. 2, a gate line 120 is formed on an insulating substrate 110. The insulating substrate 110 may include an insulating material such as transparent glass, silicon, or plastic.

The gate line 120 transmits a gate signal received from a gate driving circuit (not shown) and extends in a first direction (horizontal direction of FIG. 1). Further, the gate line 120 includes a gate electrode 121 extending in a second direction perpendicular to the first direction (vertical direction of FIG. 1).

The gate electrode 121 includes a connection section 121a and an electrode section 121b. The dimensions of the electrode section 121b in the first and second directions are greater than those of the connection section 121a. However, the scope of the present invention is not limited thereto. In detail, the electrode section 121b may have the same dimensions as the connection section 121a. Meanwhile, the gate electrode 121 may also be formed by expanding the gate line 120 in the second direction.

For convenience of description, FIG. 1 and FIG. 2 show only one gate line 120, however, a plurality of gate lines 120 are formed on the insulating substrate 110 such that the gate lines 120 are connected with a plurality of TFTs arranged in pixel areas, respectively.

The gate driving circuit, which generates the gate signal transferred to the gate line 110, may be mounted on a flexible printed circuit board (not shown) attached to the insulating substrate 110, may be directly mounted on the insulating substrate 110, or may be integrated on the insulating substrate 110. When the gate driving circuit is integrated on the insulating substrate 110, the gate line 120 may extend such that the gate line 120 is directly connected to the gate driving circuit.

The gate line 120 and the gate electrode 121 may include an aluminum-based metal such as aluminum or an aluminum alloy, a silver-based metal such as silver or a silver alloy, a copper-based metal such as copper or a copper alloy, a molybdenum-based metal such as molybdenum or a molybdenum alloy, chrome, tantalnum, or tungsten.

In addition, the gate line 120 and the gate electrode 121 may have a multi-layer structure including two or more conductive layers (not shown) containing different materials from each other. For example, the gate line 120 and the gate electrode 121 may have a dual conductive layer structure including a transparent conductive oxide such as ITO or IZO, and a metal material having low resistance as described above.

Then, a gate insulating layer 130 is formed on the gate line 120 and the gate electrode 121.

The gate insulating layer 130 may include an organic insulating layer containing a soluble high-molecular weight compound such as polyamide, polyvinyl alcohol, fluorine, or parylene, or an inorganic insulating layer such as silicon nitride.

Next, a data line 140, which includes a source electrode 141, and a drain electrode 143, is formed on the gate insulating layer 130.

The data line 140 transmits a data signal received from a data driving circuit (not shown) and crosses the gate line 120 by extending in the second direction.

The source electrode 141 includes a linear section 141a extending in the first direction toward the electrode section 121b of the gate electrode 121, and an extension section 141b extending from an end of the linear section 141a in the second direction.

The data driving circuit that generates the data signal may be mounted on a flexible printed circuit board attached to the insulating substrate 110, may be directly mounted on the insulating substrate 110, or may be integrated on the insulating substrate 110.

When the data driving circuit is integrated on the insulating substrate 110, the data line 140 may extend such that the data line 140 is directly connected to the data driving circuit.

The drain electrode 143, which may be in the form of an island and is spaced apart from the source electrode 141, includes a linear section 143a extending in the first direction, and an extension section 143b extending from an end of the linear section 143a in the second direction. The extension section 143b of the drain electrode 143 is parallel to the extension section 141b of the source electrode 141 and faces the extension section 141b.

The extension section 141b of the source electrode 141 and the extension section 143b of the drain electrode 143 may have a length that is less than or equal to the length of the electrode section 121b of the gate electrode 121 in the second direction. Thus, a ratio (W/L) of a width to a channel length of a semiconductor may increase, so that the characteristics of a TFT may be improved.

The data line 140, the source electrode 141, and the drain electrode 143 may include an aluminum-based metal such as aluminum or an aluminum alloy, a silver-based metal such as silver or an silver alloy, a copper-based metal such as copper or an copper alloy, a molybdenum-based metal such as molybdenum or an molybdenum alloy, chrome, tantalum, titanium, or tungsten.

In addition, the data line 140, the source electrode 141, and the drain electrode 143 may be formed to have a multi-layer structure including two or more conductive layers (not shown) having different materials from each other. For example, the gate line 120 and the gate electrode 121 may have a dual layer structure including a transparent conductive oxide such as ITO or IZO and a metal material having low resistance as described above. Parts of the data line 140, the source electrode 141, and the drain electrode 143, which contact a semiconductor layer 160, may have a single layer structure in order to improve contact characteristics with the semiconductor layer 160, and remaining parts of the data line 140, the source electrode 141, and the drain electrode 143 may have a dual layer structure including a conductive oxide and a metal material having low resistance.

Then, a bank insulating layer 150 is formed on the insulating substrate 110 on which the data line 140, the source electrode 141, and the drain electrode 143 are formed.

The bank insulating layer 150 includes a first contact hole 210 partially exposing the source electrode 141 and the drain electrode 143, and a second contact hole 220 exposing an end portion of the linear section 143a of the drain electrode 143.

The area of the first contact hole 210 may be smaller than that of the electrode section 121b of the gate electrode 121 to prevent photo leakage from occurring when the semiconductor layer 160 formed in the first contact hole 210 is directly exposed to light passing through the insulating substrate 110.

In FIG. 1, the first contact hole 210 has a rectangular shape. However, the scope of the present invention is not limited thereto. For example, the first contact hole 210 may have various shapes such as oval or circular shapes.

The semiconductor layer 160 is formed in the first contact hole 210, so that a part of the semiconductor layer 160 contacts the source electrode 141 and the drain electrode 143. The semiconductor layer 160 may include an organic semiconductor, a nanoparticle, or an inorganic semiconductor.

The inorganic semiconductor may include silicon, and the organic semiconductor may include an oligomer or a polymer having a structure in which electrons can be easily shifted, such as a conjugated system.

The organic semiconductor may include a low molecular weight compound or a high molecular weight compound dissolved in an aqueous solution or an organic solvent. Further, the organic semiconductor may be formed using derivatives, which are obtained by combining a conjugated system low molecular weight compound with a hydrophilic or hydrophobic functional group, in order to apply a low molecular weight compound having low solubility to a solution process.

For example, the organic semiconductor used in the semiconductor layer 160 may include pentacene, tetracene, anthracene, naphthalene, α-6T, α-4T, perylene or derivatives thereof, rubrene or derivatives thereof, coronene or derivatives thereof, perylene tetracarboxylic diimide or derivatives thereof, perylene tetracarboxylic dianhydride or derivatives thereof, phthalocyanine or derivatives thereof, naphthalene tetracarboxylic diimide or derivatives thereof, naphthalene tetracarboxylic dianhydride or derivatives thereof, conjugated high molecular weight derivatives containing substituted or non-substituted thiophene, or conjugated high molecular weight derivatives containing substituted fluorine.

The semiconductor layer 160 can be formed in the first contact hole 210 by dropping ink containing semiconductor material through an inkjet method.

The gate electrode 121, the source electrode 141, and the drain electrode 143 form a TFT together with the semiconductor layer 160, and the semiconductor layer 160 serves as a channel between the source electrode 141 and the drain electrode 143.

Then, a light blocking layer 170 is formed on the semiconductor layer 160.

The light blocking layer 170 may prevent the semiconductor layer 160 from deteriorating due to external light, and may prevent the generation of a photo leakage current. The light blocking layer 170 may include a black pigment. For example, the black pigment may include carbon black, chrome oxide, iron oxide, titan black, phenylene black, aniline black, cyanine black, or nigrosine black.

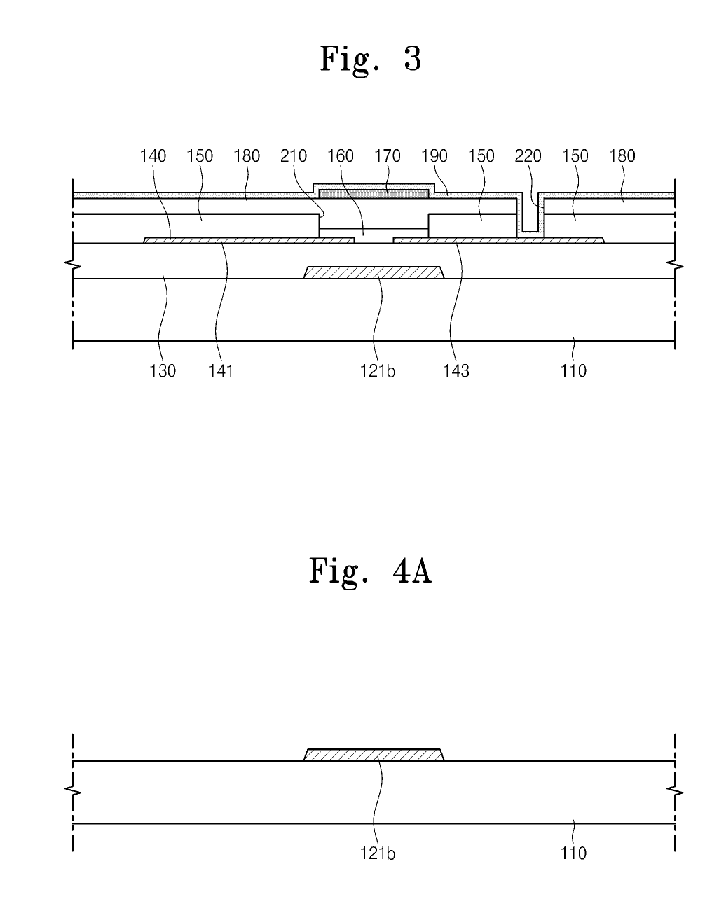

The light blocking layer 170 may be formed below a protective layer 180 as shown in FIG. 2, or may also be formed above the protective layer 180 as shown in FIG. 3 showing the section of a TFT array panel according to another exemplary embodiment of the present invention.

The protective layer 180 is formed on the bank insulating layer 150 and the light blocking layer 170.

The second contact hole 220 of the bank insulating layer 150 extends through the protective layer 180. The protective layer 180 may prevent the semiconductor layer 160 from being damaged during the fabricating process of the TFT array panel and after the fabricating process.

A pixel electrode 190 is formed on the protective layer 180.

Part of the pixel electrode 190 contacts the drain electrode 143 through the second contact hole 220 in the bank insulating layer 150 and the protective layer 180. Thus, the pixel electrode 190 may receive a data voltage from the drain electrode 143.

After receiving the data voltage, the pixel electrode 190 generates an electric field together with a common electrode (not shown) that is formed on a common electrode array panel facing the TFT array panel and receives a common voltage, thereby driving electrophoresis particles (not shown) between the pixel electrode 190 and the common electrode.

For example, the pixel electrode 190 may include a transparent conductive oxide, such as ITO or IZO.

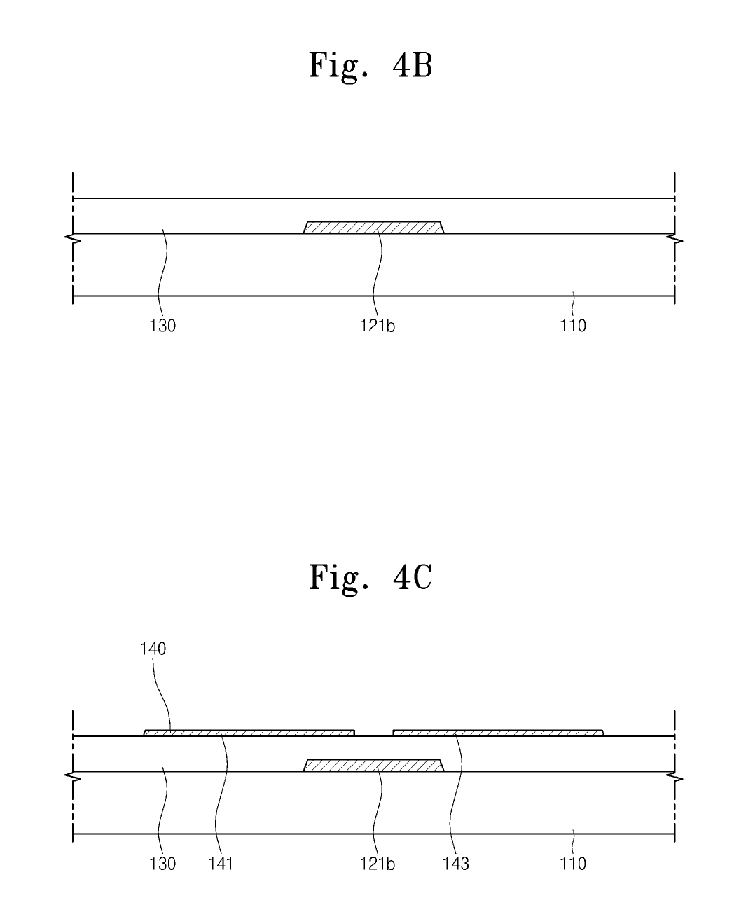

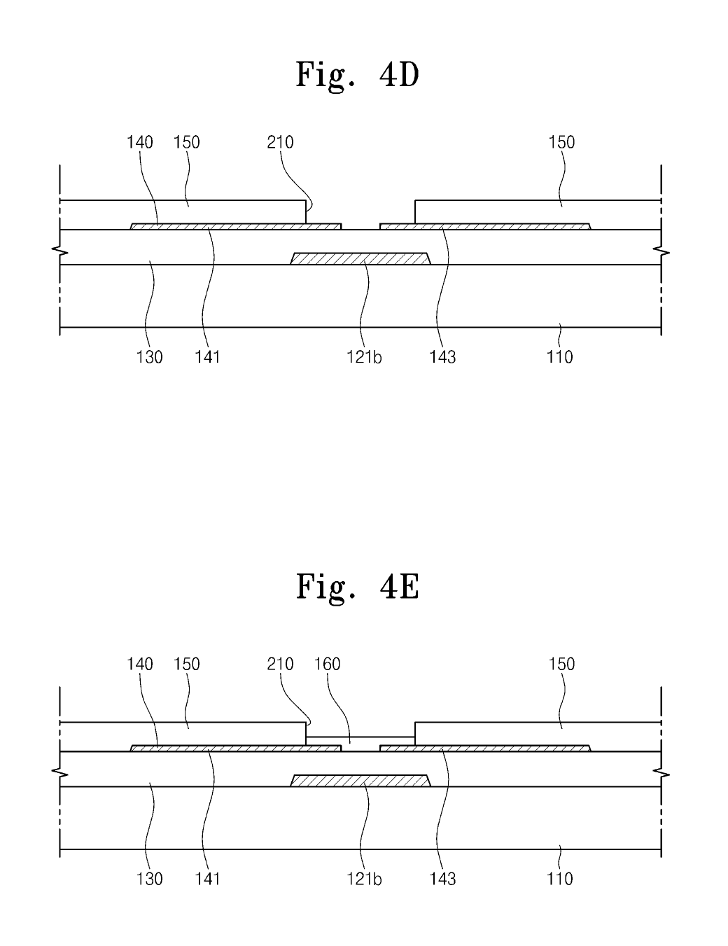

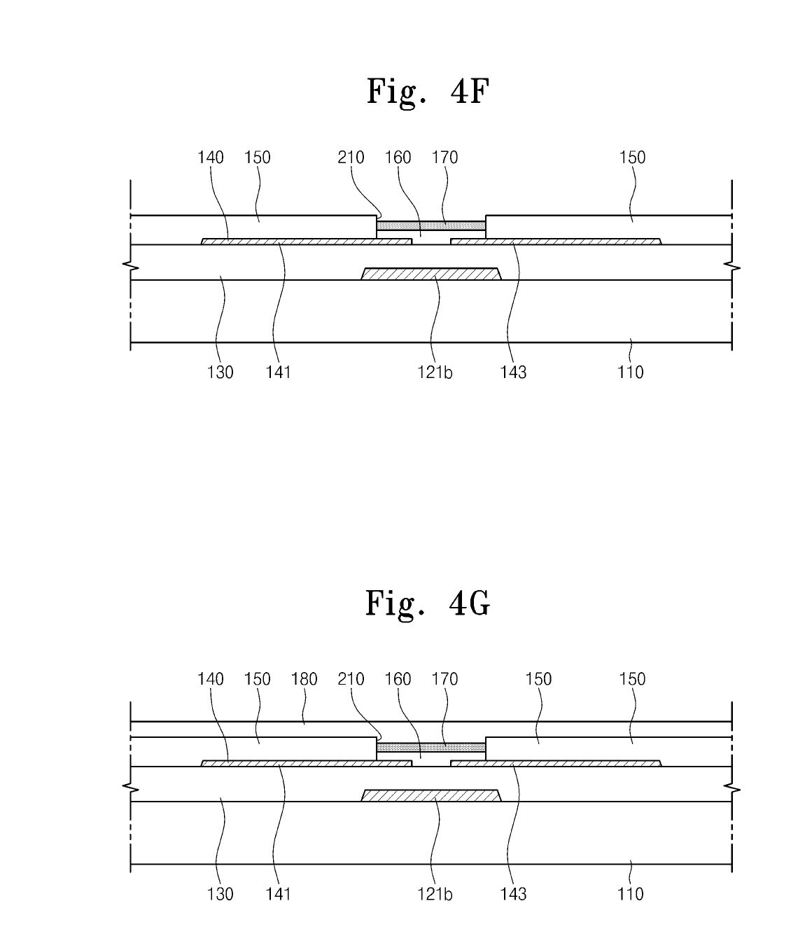

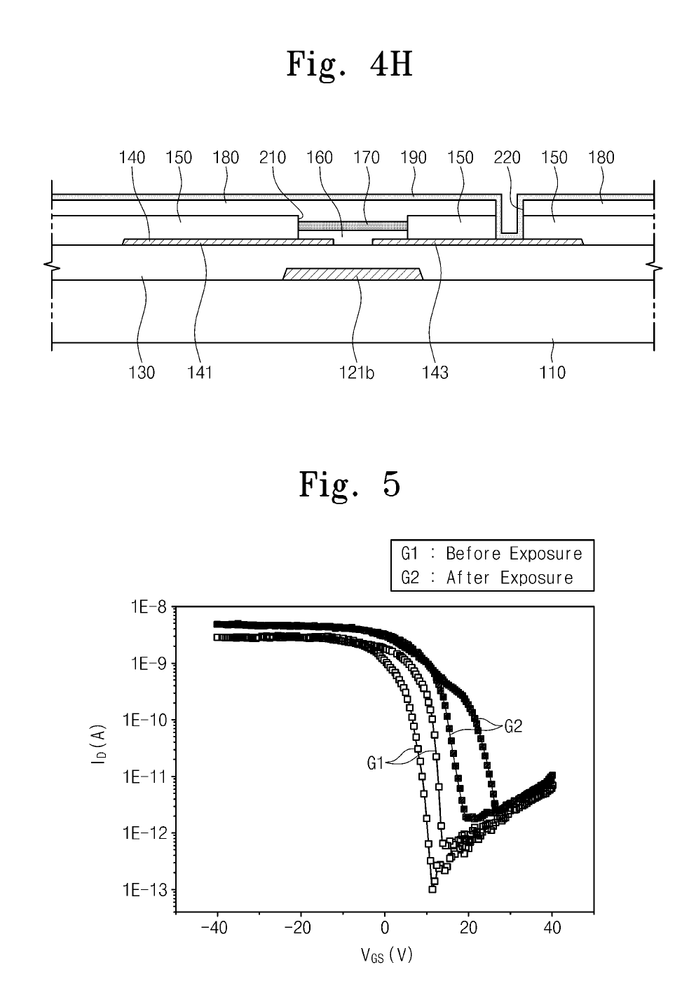

Hereinafter, a method of manufacturing the TFT array panel as shown in FIG. 1 and FIG. 2 will be described in detail with reference FIG. 4A, FIG. 4B, FIG. 4C, FIG. 4D, FIG. 4E, FIG. 4F, FIG. 4G, and FIG. 4H.

FIGS. 4A, FIG. 4B, FIG. 4C, FIG. 4D, FIG. 4E, FIG. 4F, FIG. 4G, and FIG. 4H are sectional views showing a method of manufacturing the TFT array panel according to an exemplary embodiment of the present invention.

Referring to FIG. 4A, FIG. 4B, FIG. 4C, FIG. 4D, FIG. 4E, FIG. 4F, FIG. 4G, and FIG. 4H, a metal thin film such as aluminum or molybdenum or a metal thin film and a transparent conductive oxide thin film such as ITO or IZO are formed on the insulating substrate 110 including insulating material such as transparent glass, silicon, or plastic. Then, the gate line 120 (see FIG. 1) and the gate electrode 121 (see FIG. 1) are formed by etching the thin films using an etchant.

Next, as shown in FIG. 4B, the gate insulating layer 130 is formed on the gate line 120 and the gate electrode 121 by laminating an organic insulating layer containing a soluble high molecular weight compound such as polyamide, polyvinyl alcohol, fluorine, or parylene, or an inorganic insulating layer such as silicon nitride on the gate line 120 and the gate electrode 121.

Then, referring to FIG. 4C, a metal thin film, which may include aluminum or molybdenum, or a metal thin film and a transparent conductive oxide thin film such as ITO or IZO is formed on the gate insulating layer 130. Then, the data line 140, the source electrode 141, and the drain electrode 143 are formed by etching the thin films using an etchant.

Thereafter, as shown in FIG. 4D, a first organic insulating layer is coated on the data line 140, the source electrode 141, and the drain electrode 143, and then is subjected to development and etching processes, thereby forming the bank insulating layer 150 having the first contact hole 210. The first contact hole 210 partially exposes the source electrode 141 and the drain electrode 143.

Referring to FIG. 4E, ink containing semiconductor material is dropped into the first contact hole 210 through an inkjet method, and then dried to form the semiconductor layer 160. In order to form the semiconductor layer 160, an organic semiconductor, a nanoparticle or an inorganic semiconductor may be used. The inorganic semiconductor may include silicon, and the organic semiconductor may include an oligomer or a polymer having a structure in which electrons can be easily shifted, such as a conjugated system.

Referring to FIG. 4F, the light blocking layer 170 including a black pigment is formed on the semiconductor layer 160. For example, the black pigment may include carbon black, chrome oxide, iron oxide, titan black, phenylene black, aniline black, cyanine black, or nigrosine black.

The light blocking layer 170 may be formed using a composition for a light blocking layer, which contains a black pigment, a binder resin, and a solvent. The composition may include 1 to 10 weight % of the black pigment, 2 to 10 weight % of the binder resin, and 70 to 95 weight % of the solvent in order to improve the performance and facilitate the process of forming the light blocking layer 170. Further, a thermosetting material, a dispersing agent, or a surface active agent may be added to the composition.

Differently from the present exemplary embodiment, after the protective layer 180 is formed and the light blocking layer 170 is formed thereon, the pixel electrode 190 may be formed on the light blocking layer 170, thereby forming the TFT array panel having the structure shown in FIG. 3.

As shown in FIG. 4G, the protective layer 180 is formed on the bank insulating layer 150 and the light blocking layer 170 and may include organic or inorganic insulating material.

Thereafter, referring to FIG. 4H, the second contact hole 220 is formed by etching the protective layer 180 and the bank insulating layer 150, and then a transparent conductive oxide such as ITO or IZO is deposited thereon to form the pixel electrode 190. Thus, the pixel electrode 190 contacts the drain electrode 143 through the contact hole 220.

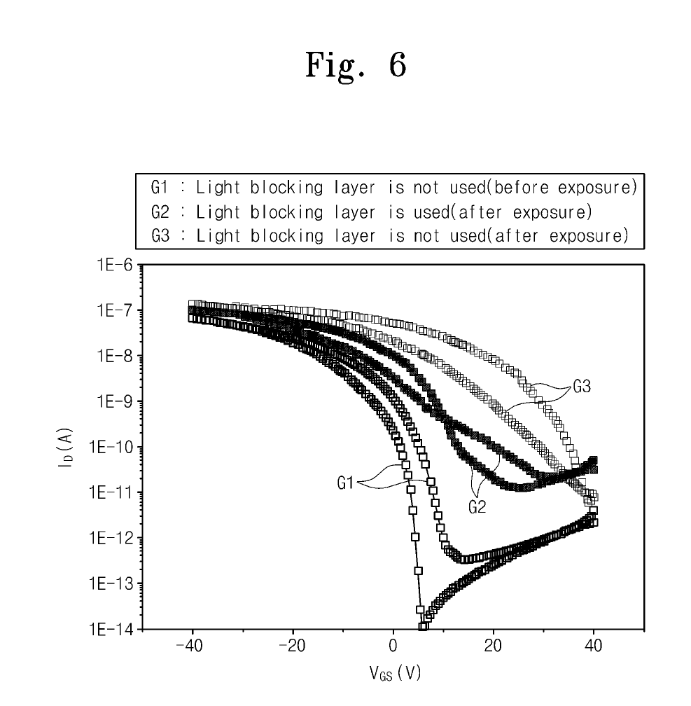

Hereinafter, the effect of the TFT array panel including the light blocking layer 170 as described above will be described with reference to the graphs of FIG. 5, and FIG. 6.

FIG. 5 is a graph showing a result obtained by performing an exposure experiment relative to an organic TFT unit device without a light blocking layer, and shows V_{GS}-I_{D} curves before and after the unit device is subject to an exposure process. FIG. 6 is a graph showing a result obtained by performing an exposure experiment relative to an organic TFT unit device using the light blocking layer and an organic TFT unit device without a light blocking layer, and shows V_{GS}-I_{D} curves before and after the unit devices are subject to an exposure process.

Referring to FIG. 5, when the light blocking layer 170 is omitted, a threshold voltage Vₜₕ is increased and an off current I_{off} is increased. Referring to FIG. 6, when the light blocking layer 170 is omitted, a threshold voltage Vₜₕ and an off current I_{off} are significantly increased after the exposure process. Therefore, the light blocking layer 170 may be used to prevent degradation of the characteristics of the unit device.

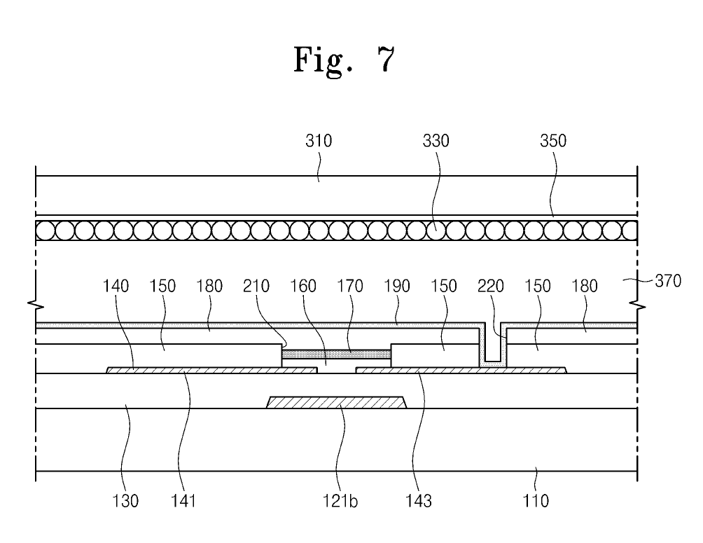

FIG. 7 is a sectional view of a flat panel display having the TFT array panel according to an exemplary embodiment of the present invention. FIG. 7 shows an electrophoresis apparatus as one example of the flat panel display. However, the flat panel display of the present exemplary embodiment can be applied to various flat panel displays such as liquid crystal displays or organic light emitting apparatuses.

The flat panel display of the present exemplary embodiment may be obtained by laminating sheets from E-INK Corporation on the TFT array panel.

In more detail, the sheet includes an insulating substrate 310, a common electrode 350 formed on one surface of the insulating substrate 310, black matrices (not shown) disposed on the common electrode 350, electrophoresis particles 330 arranged in a pixel space defined by the black matrices, and an adhesive 370 sealing the electrophoresis particles 330 in the pixel space.

The adhesive 370 allows the sheets to adhere to the TFT array panel. The common electrode 350 may include ITO or IZO.

According to the above, performance degradation of the TFT array panel, which is caused by external light can be prevented, so that device characteristics such as threshold voltage shift and off current characteristics of the TFT array panel may be improved. Thus, the display quality of a display apparatus may be improved.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A thin film transistor (TFT) array panel, comprising:
a substrate;
a gate line disposed on the substrate and having a gate electrode;
a gate insulating layer disposed on the gate line;
a data line disposed on the gate insulating layer and crossing the gate line;
a source electrode connected to the data line;
a drain electrode spaced apart from the source electrode;
a semiconductor layer connected to the source electrode and the drain electrode to form a channel;
a light blocking layer disposed on the semiconductor layer to block light incident to the semiconductor layer; and
a pixel electrode contacting the drain electrode.

2. The TFT array panel of claim 1, wherein the light blocking layer comprises a black pigment.

3. The TFT array panel of claim 2, wherein the black pigment comprises carbon black, chrome oxide, iron oxide, titan black, phenylene black, aniline black, cyanine black, or nigrosine black.

4. The TFT array panel of claim 1, further comprising a protective layer to protect the semiconductor layer.

5. The TFT array panel of claim 4, wherein the protective layer is disposed between the light blocking layer and the semiconductor layer.

6. The TFT array panel of claim 4, wherein the light blocking layer is disposed between the protective layer and the semiconductor layer.

7. The TFT array panel of claim 4, wherein the protective layer is formed through a spin coating method or an inkjet method.

8. The TFT array panel of claim 1, further comprising a bank insulating layer that defines an area where the semiconductor layer is disposed.

9. The TFT array panel of claim 1, wherein the pixel electrode comprises a transparent conductive material or an opaque conductive material.

10. A method of fabricating a thin film transistor (TFT) array panel, comprising:
forming a gate electrode and a gate line on a substrate;
forming a gate insulating layer on the gate line;
forming a source electrode, a drain electrode, and a data line on the gate insulating layer;
forming a semiconductor layer between the source electrode and the drain electrode;
forming a light blocking layer overlapping with the semiconductor layer to block light; and
forming a pixel electrode to contact with the drain electrode.

11. The method of claim 10, wherein the light blocking layer comprises a black pigment.

12. The method of claim 11, wherein the light blocking layer further comprises a binder resin and a solvent.

13. The method of claim 12, wherein the light blocking layer comprises 1 to 10 weight % of the black pigment, 2 to 10 weight % of the binder resin, and 70 to 95 weight % of the solvent.

14. The method of claim 11, wherein the black pigment comprises carbon black, chrome oxide, iron oxide, titan black, phenylene black, aniline black, cyanine black, or nigrosine black.

15. The method of claim 12, wherein the light blocking layer further comprises a thermosetting material, a dispersing agent, or a surface active agent.

16. The method of claim 10, wherein the semiconductor layer is formed by an inkjet method.

17. A flat panel display, comprising:
a thin film transistor (TFT) array panel;
a common electrode array panel facing the TFT array panel; and
electrophoresis particles disposed between the TFT array panel and the common electrode array panel,
wherein the TFT array panel comprises:
a substrate;
a gate line disposed on the substrate and having a gate electrode;
a gate insulating layer disposed on the gate line;
a data line disposed on the gate insulating layer and crossing the gate line;
a source electrode connected to the data line;
a drain electrode spaced apart from the source electrode;
a semiconductor layer connected with to the source electrode and the drain electrode to form a channel;
a light blocking layer disposed on the semiconductor layer to block light incident to the semiconductor layer; and
a pixel electrode contacting the drain electrode.

18. The flat panel display of claim 17, wherein the light blocking layer comprises a black pigment.

19. The flat panel display of claim 18, wherein the black pigment comprises carbon black, chrome oxide, iron oxide, titan black, phenylene black, aniline black, cyanine black, or nigrosine black.

20. The flat panel display of claim 17, further comprising a protective layer to protect the semiconductor layer.

21. The flat panel display of claim 17, further comprising a bank insulating layer that defines an area where the semiconductor layer is disposed.
